(19) United States
(12) Patent Application Publication
(10) Pub. No.: US 2014/0192272 A1
(43) Pub. Date: Jul. 10, 2014

(54) FLAT PANEL DISPLAY DEVICE AND METHOD FOR MANUFACTURING THE SAME

(71) Applicant: Hwasug KANG, Gyeonggi-do (KR)

(72) Inventor: Hwasug KANG, Gyeonggi-do (KR)

(73) Assignee: SY TECH CO., LTD., Seoul (KR)

(21) Appl. No.: 14/086,141

(22) Filed: Nov. 21, 2013

(30) Foreign Application Priority Data
Jan. 4, 2013 (KR) 2013-0001286

(51) Int. Cl. G02F 1/1333; H05K 7/02

(52) U.S. Cl. CPC G02F 1/13338; H05K 7/02
USPC 349/12; 445/24; 361/728

(57) ABSTRACT

There are provided a flat panel display device in which a flat display panel and an optical member are layered and fixed to each other without using an OCA (Optical Clear Adhesive) film and a method for manufacturing the same.

A flat panel display device according to an exemplary embodiment of the present invention includes a display module that is formed by layering a flat display panel and one or more optical members having a pair of flat planes; and an adhesive that occupies mold spaces formed so as to include sides of the display module and is cured while adhering to the sides of the display module, in which the display module is fixed by the cured adhesive.

### CROSS-REFERENCE TO RELATED APPLICATIONS

This application claims the priority of Korean Patent Application No. 10-2013-0001286 filed on Jan. 4, 2013, in the Korean Intellectual Property Office, the disclosure of which is incorporated herein by reference.

### BACKGROUND OF THE INVENTION

1. Field of the Invention

The present invention relates to a flat panel display device and a method for manufacturing the same and more particularly, to a flat panel display device in which a flat display panel and an optical member are layered and fixed to each other without using an OCA (Optical Clear Adhesive) film and a method for manufacturing the same.

2. Description of the Related Art

A FPD (Flat Panel Display) device is widely used in devices such as a television (TV), a cellular phone, a notebook computer, and a tablet PC (Personal Computer). Examples of the FPD display include a PDP (Plasma Display Panel) device, a LCD (Liquid Crystal Display) device, an OLED (Organic Light-Emitting Display) device, and an electrophoretic display device.

FIG. 1 is a schematic diagram showing a structure of an existing electrophoretic display device 1. Referring to FIG. 1, the existing electrophoretic display device 1 includes an anti-glare film 2, a light guide plate 3, a touch panel 4, and an electrophoretic display panel 5.

The electrophoretic display panel 5 displays an image, and the displayed image is viewed by an outside user after sequentially passing the touch panel 4, the light guide panel 3 and the anti-glare film 2.

Here, the touch panel 4 serves to sense a touch of the outside user, and the light guide plate 3 functions to allow the image displayed on the electrophoretic display panel 5 to be seen under a dark environment by transferring light emitted from a LED on a side to the outside. Further, the anti-glare film 2 functions to prevent scattered reflection to enable the image to be clearly viewed. The anti-glare film 2 is attached to a bezel 7 by a PSA (Pressure Sensitive Adhesive) 6. Here, an OCA film may be used instead of the PSA.

The anti-glare film 2, the light guide plate 3, the touch panel 4 and the electrophoretic display panel 5 are in a thin-plate type or a film type. The anti-glare film, the light guide plate, the touch panel and the electrophoretic display panel are layered and fixed to each other, and the components are generally attached to each other with OCA (Optical Clear Adhesive) films 8 interposed therebetween.

However, when the components are attached to each other by using the OCA films 8, the number of processes for sticking the OCA films to the components excessively increases. Further, since it is difficult to stick the OCA films to all components at once, it is required to separately stick the OCA films to the components, so that it takes time to stick the OCA films to the components. Furthermore, the sticking processes are complicated, so that there is a problem of poor productivity.

Moreover, even when a defect occurs in any one process of the OCA sticking processes, since all components are discarded, there is a problem of an increase in manufacturing cost.

In addition, since the OCA film 8 has a thickness of about 0.05 mm, there is a problem that the total thickness of the display device 1 becomes thick by using the OCA films 8.

### SUMMARY OF THE INVENTION

In order to solve the aforementioned problems, an aspect of the present invention provides a method for manufacturing a flat panel display device with which it is possible to increase productivity by minimizing the number of OCA sticking processes or omitting a part of the OCA sticking processes to increase a yield and reduce a manufacturing time.

An aspect of the present invention also provides a flat panel display device capable of being implemented as an ultra-thin type by using no OCA films or using the OCA films as little as possible.

The objects of the present invention are not limited to the aforementioned objects, and other objects, which are not mentioned above, will be apparent to those skilled in the art from the following description.

In order to achieve the abject, a flat panel display device according to an exemplary embodiment of the present invention includes a display module that is formed by layering a flat display panel and one or more optical members having a pair of flat planes; and an adhesive that occupies mold spaces formed so as to include sides of the display module and is cured while adhering to the sides of the display module, in which the flat display panel and the one or more optical members that constitute the display module are fixed to each other by the cured adhesive.

The adhesive is a light curing adhesive or a heat curing adhesive.

The flat display panel is an electrophoretic display panel, the optical members include a touch panel and a light guide plate, the display module is formed by sequentially layering the electrophoretic display panel, the touch panel and the light guide plate, and an anti-glare film or a cover glass is attached to an outside of the light guide plate.

The flat display panel is a liquid crystal display panel, the optical members include a reflection plate, a light guide plate, and a touch panel, the display module is formed by sequentially layering the reflection plate, the light guide plate, the liquid crystal display panel and the touch panel, and n anti-glare film or a cover glass is attached to an outside of the touch panel.

In order to achieve the object, a method for manufacturing a flat panel display device according to an exemplary embodiment of the present invention includes forming a display module by layering a flat display panel and one or more optical members having a pair of flat planes; forming dams so as to form mold spaces including sides of the display module; injecting an adhesive into the mold spaces while applying a pressure so as to allow the flat display panel and the one or more optical members that constitute the display module to come in close contact with each other; and curing the adhesive, in which the flat display panel and the one or more optical members that constitute the display module are fixed to each other by the adhesive.

The forming of the dams includes forming transparent side dams so as to face the sides of the display module, the adhesive is a light curing adhesive, and in the curing of the adhesive, light is radiated through the side dams to cure the light curing adhesive.

The forming of the dams includes forming side dams so as to face the sides of the display module and forming a lower dam so as to form bottoms of the mold spaces, and in which the method for manufacturing a flat panel display device further includes removing the lower dam after the curing of the adhesive, and attaching an outmost plate to a bottom of the display module after removing the lower dam.

The outmost plate is at least one of a cover glass, an anti-glare film, and a cover film.

A material through which light is not transmitted is printed at edges of the outmost plate so as to allow an image display area of the flat display panel to be viewed from the outside.

In order to achieve the object, a flat panel display device according to an exemplary embodiment of the present invention is manufactured by the manufacturing method as described above.

According to a flat panel display device and a method for manufacturing the same of the invention, it is possible to increase productivity by minimizing the number of OCA sticking processes or omitting a part of the OCA sticking processes to increase a yield and reduce a manufacturing time.

Further, it is possible to implement a flat panel display device as an ultra-thin type by using no OCA films or using the OCA films as little as possible.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic diagram showing a structure of an existing electrophoretic display device.

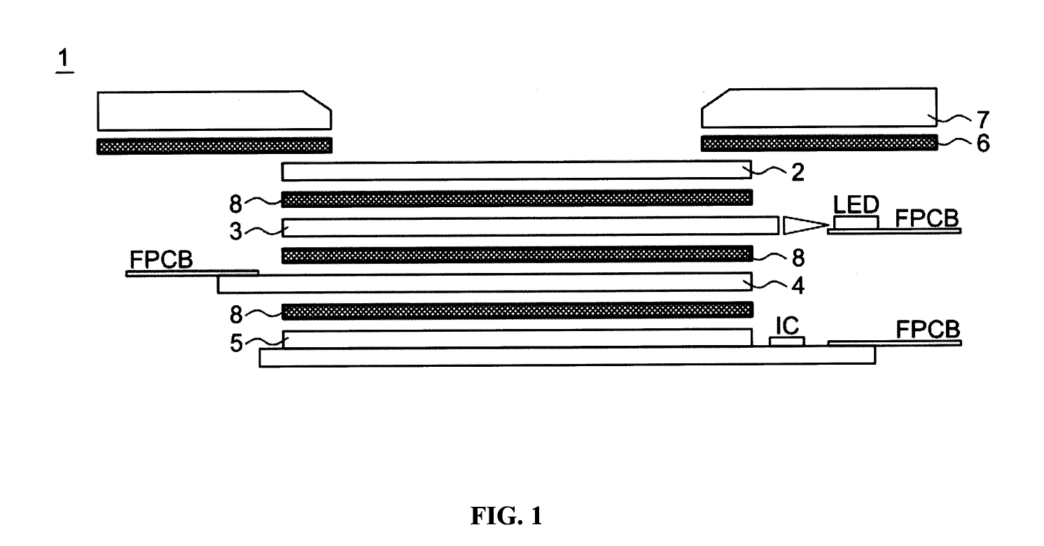

FIG. 2 is a schematic side view of a flat panel display device 100 according to an exemplary embodiment of the present invention.

FIG. 3 is a flowchart for describing a method for manufacturing the flat panel display device according to the present invention.

FIGS. 4A to 4E are side views of the flat panel display device in steps for describing the manufacturing method of FIG. 3.

FIG. 5 is a schematic side view of a flat panel display device according to a first exemplary embodiment of the present invention.

FIG. 6 is a schematic side view of a flat panel display device according to a second exemplary embodiment of the present invention.

FIG. 7 is a schematic side view of a flat panel display device according to a third exemplary embodiment of the present invention.

### DETAILED DESCRIPTION OF THE PREFERRED EMBODIMENT

Various advantages and features of the present invention and methods accomplishing thereof will become apparent from the following description of embodiments with reference to the accompanying drawings. However, the present invention is not limited to exemplary embodiment disclosed herein but will be implemented in various forms. The exemplary embodiments are provided by way of example only so that a person of ordinary skilled in the art can fully understand the disclosures of the present invention and the scope of the present invention. Therefore, the present invention will be defined only by the scope of the appended claims.

Indicating that elements or layers are “on” other elements or layers include both a case in which the corresponding elements are just above other elements and a case in which the corresponding elements are intervened with other layers or elements.

Although first, second, and the like are used in order to describe various components, the components are not limited by the terms. The above terms are used only to discriminate one component from the other component. Therefore, a first component mentioned below may be a second component within the technical spirit of the present invention.

The same reference numerals indicate the same elements throughout the specification.

In the drawings, size and thickness of each element are arbitrarily illustrated for convenience of description, and the present invention is not necessarily limited to those illustrated in the drawings.

Respective features of various exemplary embodiments of the present invention can be partially or totally joined or combined with each other and as sufficiently appreciated by those skilled in the art, various interworking or driving can be technologically achieved and the respective exemplary embodiments may be executed independently from each other or together executed through an association relationship.

Hereinafter, a flat panel display apparatus according to the present invention will be described with reference to the accompanying drawings.

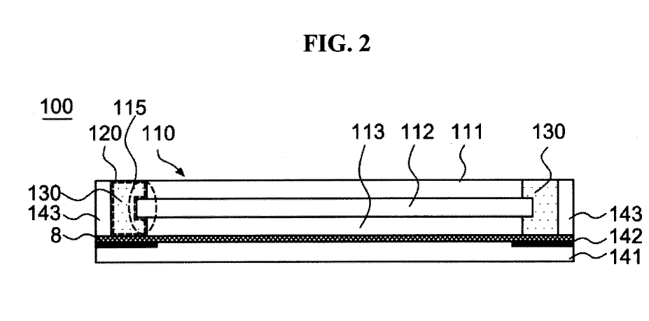

FIG. 2 is a schematic side view of a flat panel display device 100 according to an exemplary embodiment of the present invention.

Referring to FIG. 2, the flat panel display device 100 according to the present invention includes a display module 110 and an adhesive 130 cured while adhering to sides 115 of the display module 110.

The display module 110 includes two or more layers, and FIG. 2 illustrates that the display module includes a first layer 111 to a third layer 113. At least one layer of the plurality of layers 111 to 113 of the display module 110 is a flat display panel, and the other layers are optical members having a pair of flat planes.

Here, the flat display panel means thin type display panels such as a plasma display panel, a liquid crystal display panel, an organic light-emitting display panel, and an electrophoretic display panel.

Further, the optical member includes a member that transmits an image by giving an optical effect to the image displayed on the flat display panel, changing a path of light, reflecting light, or being formed to be transparent. The optical member has a pair of flat planes and is in a thin film type or a plate type. Examples of the optical member may include a prism sheet, a diffusion sheet, a light guide plate, a back light unit, a reflection sheet, a touch panel, an anti-glare film, and a cover glass.

The display module 110 is formed by layering the optical members and the flat display panel described above. For example, an electrophoretic display device may be configured such that the first layer 111 is an electrophoretic display panel, the second layer 112 is a touch panel, and the third panel 113 is a light guide plate (see a first exemplary embodiment to be described below). Further, for example, a liquid crystal display device may be configured such that the first layer 111 is a back light unit including a reflection sheet, the second layer 112 is optical sheets such as a light guide plate, a diffusion sheet, and a prism sheet, and the third panel 113 is a liquid crystal display panel (see a second exemplary embodiment to be described below). The display module 1110 is not limited to the examples, and may include many layers other than the three layers 111 to 113 of FIG. 2. An arrangement of the layers may be different depending on an implement example of the display device.

Moreover, the display module 110 is not manufactured by attaching surfaces of the respective layers 111 to 113 by OCA films, but is manufactured by layering the respective layers 111 to 113 on top of each other and fixing the layers by the cured adhesive 130 at the sides 115 of the display module 110. However, all the surfaces of the layers 111 to 113 need not be attached, and only surfaces of some layers of the layers may be attached. For example, the display module 110 may be manufactured by attaching thin optical sheets such as a diffusion sheet and a prism sheet and then layering the attached sheets and other layers.

Mold spaces 120 which are spaces occupied by the adhesive 130 are formed so as to include the sides 115 of the display module 110. The first layer 111 to the third layer 113 can be fixed by curing the adhesive 130 in the mold spaces 120 and sticking the cured adhesive to the sides 115 of the display module 110. By forming the mold spaces 120 at the sides 115 in the vicinity of edges of the display module 110, it is possible to firmly fix the display module 110. Further, since sizes of the layers 111 to 113 of the display module 110 are different from each other, the sides 115 of the display module 110 are formed in an uneven shape other than a straight shape and the adhesive 130 infiltrate into the uneven portions. Thus, the display module 110 can be more firmly fixed.

Here, it is preferable to use a material that is in a liquid phase before being cured and is cured under a certain condition to exhibit an adhesion function as the adhesive 130. As the certain condition, there are various conditions such as radiating of light, heating at a certain temperature, removing of air, and elapsing of a certain time. For example, a light curing adhesive or a heat curing adhesive may be used as the adhesive 130. Especially, an ultraviolet light curing adhesive, electron ray curing adhesive, or visible ray curing adhesive may be used as the light curing adhesive depending on the kind of radiated light.

An outmost plate 141 may be attached to an outmost portion positioned in a direction where a user recognizes a screen by suing an OCA film 8. Here, the outmost plate 141 may be a cover glass or an anti-glare film. It is preferable to form light blocking layers 142, which are printed by using a material through which light is not transmitted, at edges of the outmost plate 141 so as to allow only an image display area of the flat display panel to be viewed from the outside. However, the outmost plate 141 is not limited to the aforementioned example, and may be a general cover film.

Side cases 143 are positioned at the sides while coming in contact with the cured adhesive 130. The side cases 143 may be side dams to be described below, or may be members that are separately formed.

Meanwhile, the outmost plate 141 and the side cases 143 may be separately formed as shown in FIG. 2, but may be integrally formed in a “⊂” shape (see a third exemplary embodiment). Furthermore, the outmost plate 141 and the side cases 143 may not be provided. Especially, when the outmost plate 141 is not provided, a cover glass may be used as the third layer 113.

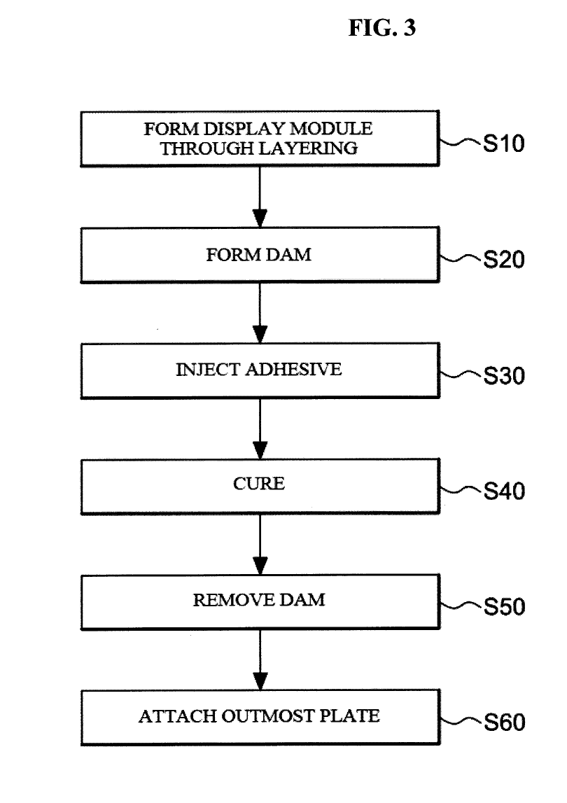

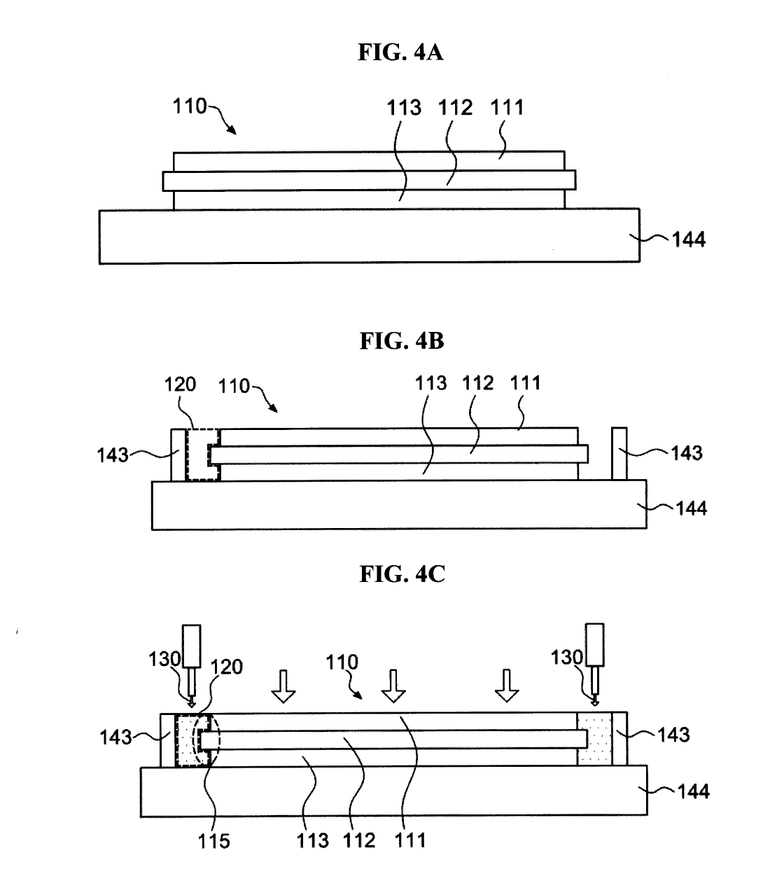

FIG. 3 is a flowchart for describing a method for manufacturing the flat panel display device according to the present invention, and FIGS. 4A to 4E are side views of the flat panel display device in steps for describing the manufacturing method of FIG. 3. Configurations of FIGS. 4A to 4E are the same as that of FIG. 2.

Referring to FIGS. 3 to 4E, the method for manufacturing the flat panel display device according to the present invention may include step S10 of forming the display module, step S20 of forming dams, step S30 of injecting the adhesive, step S40 of curing the adhesive, step S50 of removing the dams, and step S60 of attaching the outmost plate.

First, as shown in FIG. 4A, the display module 110 is formed (S10). The display module 110 is formed by layering the flat display panel and one or more optical members having a pair of flat planes. The display module 110 is formed by sequentially layering the first layer 111 to the third layer 113 on top of each other, and the display module is layered on a lower dam 144. The lower dam 144 serves as bottoms of the mold spaces 120 to be described below. The lower dam 144 may be removed after curing the adhesive 130. Further, the display module 110 may not be layered on the lower dam 144, but may be directly layered on an outer cover (not shown) such as a cover glass to serve as the lower dam 144. In such a case, it is not required to remove the outer cover after curing the adhesive.

Subsequently, as shown in FIG. 4B, dams 143 and 144 are formed (S20). The dams 143 and 144 function to restrict occupying spaces of the adhesive 130 to form the mold spaces 120 including the sides 115 of the display module 110. The dams 143 and 144 may include the lower dam 144 and the side dams 143. The side dams 143 are formed so as to face the sides 115 of the display module 110, and define limitation of the adhesive 130 to the outside.

Here, the dams 143 and 144 may be formed before forming the display module 110, or may be simultaneously formed with the display module 110. Alternatively, the dams may be formed after forming the display module 110. Otherwise, the lower dam 144 and the side dams 143 may be simultaneously formed as one body. In the present exemplary embodiment, the lower dam 144 is simultaneously formed in step S10 of forming the display module 110, and then the side dams 143 are formed. That is, the lower dam and the side dams may be separately formed in different steps.

Further, the dams 143 and 144 may be removed after curing the adhesive 130, or may be used without being removed after curing the adhesive. For example, the side dams 143 may not be removed after curing the adhesive and may serve as outer cases (corresponding to the side cases 143 of FIG. 2).

Thereafter, as shown in FIG. 4C, the adhesive 130 is injected into the mold spaces 120 (S30). At this time, by injecting the adhesive 130 while applying a pressure so as to allow the first layer 111 to the third layer 113 that constitute the display module 110 to come in close contact with each other, the adhesive 130 is prevented from infiltrating into between the layers. As the method of injecting the adhesive 130 into the mold spaces 120, a method of injecting the adhesive through an open top as shown in FIG. 4C and a method of injecting the adhesive 130 through an injection hole (not shown) formed in the side dams 143 or the lower dam 144 may be used.

Subsequently, as shown in FIG. 4D, the adhesive 130 is cured (S40). Various curing methods may be used depending on the kind of the adhesive 130. For example, when the light curing adhesive is used, light rays such as ultraviolet light, electron rays, or visible rays may be radiated from the outside to cure the adhesive. When the heat curing adhesive is used, heat from may be applied from the outside to cure the adhesive.

Meanwhile, when the light curing adhesive is used, in order to reduce a curing time, the side dams 143 and the lower dam 144 may be preferably made from a transparent material so as to transmit light.

Thereafter, the dams 143 and 144 are removed (S50). The dams 143 and 144 may be removed in various manners. For example, only the lower dam 144 may be removed, or the lower dam 144 and the side dams 143 may be all removed. When the lower dam 144 and the side dams 143 are integrally formed in a “⊂” shape, since the dams need not be removed, step S50 may not be performed.

Subsequently, as shown in FIG. 4E, the outmost plate 141 is attached (S60). For example, when the lower dam 144 to be removed as described above is used, the outmost plate 141 may be attached to a portion where the lower dam 144 has been removed. The lower dam 144 may be removed after curing the adhesive 130, and then the outmost plate 141 may be attached using the OCA film 8. Here, the outmost plate 141 may be a cover glass or an anti-glare film, and the light blocking layers 142 printed using the material through which light is not transmitted may be preferably formed at the edges of the outmost plate 141 so as to allow the image display area of the flat display panel to be viewed from the outside. However, the outmost plate 141 is not limited to the aforementioned examples, but may be a general cover film.

Meanwhile, step S60 may not be performed by using the lower dam 144 as the outmost plate 141 without separately attaching the outmost plate 141. That is, when it is not required to remove the lower dam 144, step S60 may not be performed.

According to the method for manufacturing the flat panel display device 100 as stated above, a quality test may be performed in the step of forming the display module. Only a defect portion in the display module determined as a defect in the quality test is removed and is then reassembled to manufacture the flat panel display device. Thus, it is possible to greatly reduce manufacturing cost as compared to the conventional display device capable of not being disassembled at the time of finding the defect.

Moreover, by omitting the sticking process using the OCA films 8 between the respective layers, the manufacturing cost and manufacturing time are reduced, so that it is possible to improve productivity.

In addition, since the OCA films 8 are not used, it is possible to reduce a thickness of the display device.

### First Exemplary Embodiment

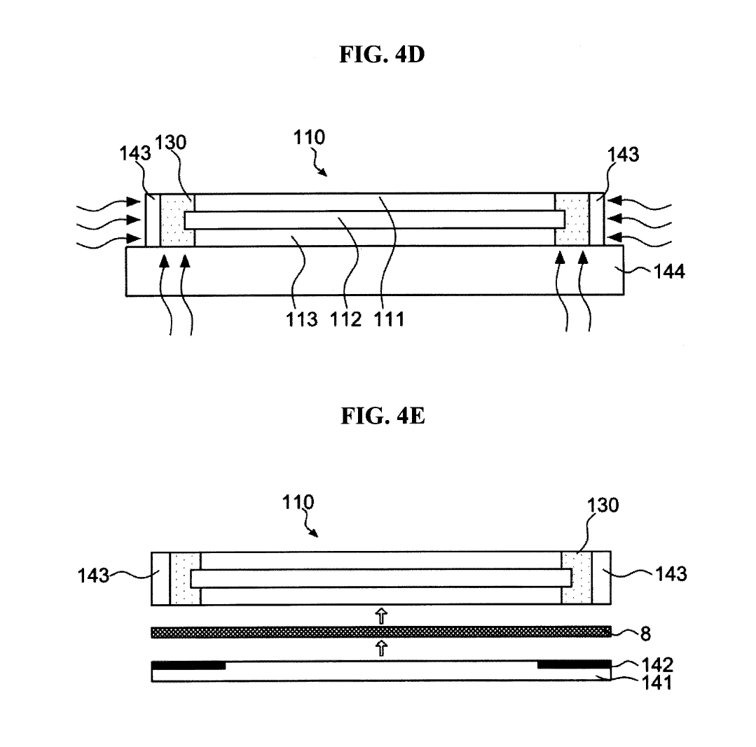

FIG. 5 is a schematic side view of a flat panel display device according to a first exemplary embodiment of the present invention.

Referring to FIG. 5, a flat panel display device 200 includes a display module 210 and adhesive 230 cured while adhering to sides of the display module 210.

The flat panel display device 200 of the present exemplary embodiment has the same configuration as that of the aforementioned flat panel display device 100 except for a configuration of the display module 210, and thus the configuration of the display module 210 will be described in detail.

The flat panel display device 200 of the present exemplary embodiment is an electrophoretic display device, and the display module 210 includes an electrophoretic display panel 211, a touch panel 212, and a light guide plate 213.

The electrophoretic display is a display using a technology which displays colors, characters and images by using fine nanoparticles moving along a positive electrode or a negative electrode when current flows. Because of low power consumption, the electrophoretic display has been widely used as electronic paper. Especially, the electrophoretic display has been used in electronic devices that are used in e-book services such as Amazon Kindle.

The electrophoretic display panel 211 is a panel serving to implement such a function, and receives a control signal from the outside through a FPCB (Flexible Printed Circuit Board) 215 and displays an image.

The touch panel 212 is a component in which when a finger or an object instead of a keyboard or a mouse touches directly a screen, a position of the touched portion is detected, the detected result is analyzed, and the analyzed result is sent to a control unit. The touch panel sends a signal to the outside by a FPCB 216. The touch panel 212 is formed by layering a film or a tempered glass on which a transparent conductive film (Indium Tin Oxide; ITO) on top and bottom plates. A resistive type or a capacitive type may be used as a driving type of the touch panel 212. Further, when an integral touchscreen type realized by being integrated with a cover glass or a display panel is adopted, the touch panel 212 need not be separately provided.

The light guide plate 213 is a member that guides light of a light source (not shown) such as a LED disposed on a side and allows an image of the electrophoretic display panel 211 to be viewed under a dark environment.

The light guide plate 213 and an anti-glare film 241 are attached to each other by using the OCA film 8. Light blocking layers 242 made from a material through which light is not transmitted may be printed at edges of the anti-glare film 241.

An adhesive 230 and side dams 243 have the same configurations as those of the adhesive 130 and the side dams 143 described above, and thus the detailed descriptions thereof will not be provided. Further, a method for manufacturing the display device 200 of the present exemplary embodiment is the same as the aforementioned method, and thus the detailed descriptions thereof will not be provided.

### Second Exemplary Embodiment

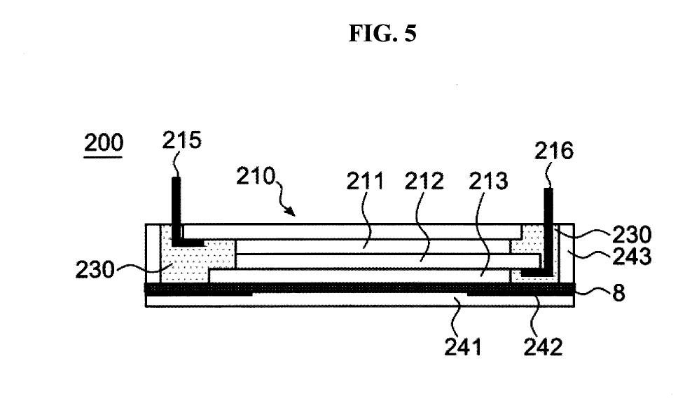

FIG. 6 is a schematic side view of a flat panel display device according to a second exemplary embodiment of the present invention.

First, referring to FIG.6, a flat panel display device includes a display module 310 and an adhesive 330 cured while adhering to sides of the display module 310.

The flat panel display device 300 of the present invention has the same configuration as those of the flat panel display devices 100 and 200 except for a configuration of the display module 310, and thus the configuration of the display module 310 will be described in detail.

The flat panel display device 300 of the present invention is an edge type liquid crystal display, and the display module 310 includes a reflection sheet 311, a light guide plate 312, an optical sheet 313, a liquid crystal display panel 314, and a touch panel 315.

The reflection sheet 311 is a member that reflects light of a light source toward the light guide plate 312 to reduce a loss of the light, and is used by coating a base material with high-reflectivity silver or a high-reflectivity polymer.

The light guide plate 312 is a plate that receives light from a light source (not shown) such as a LED disposed on a side and changes a path of the light toward a front surface.

The optical sheet includes a diffusion sheet and a prism sheet. The diffusion sheet and the prism sheet may be previously attached to each other, or may be layered without being attached.

The liquid crystal display panel 314 is abbreviated to a LCD panel, and may be any type of LCD panel such as a passive matrix type or an active matrix. The liquid crystal display panel 314 receives an image signal from the outside by a FPCB 316.

The touch panel 315 is a component in which when a finger or an object instead of a keyboard or a mouse touches directly a screen, a position of the touched portion is detected, the detected result is analyzed, and the analyzed result is sent to a control unit. The touch panel sends a signal to the outside by a FPCB 317. The touch panel 315 is formed by layering a film or a tempered glass on which a transparent conductive film (Indium Tin Oxide; ITO) on top and bottom plates. A resistive type or a capacitive type may be used as a driving type of the touch panel 315. Further, when an integral touchscreen type realized by being integrated with a cover glass 314 or a liquid crystal display panel 314 is adopted, the touch panel 315 need not be separately provided.

The cover glass 341 may be a tempered glass for covering the display module 310, and may be attached to the outside of the touch panel 315 by using the OCA film 8.

Meanwhile, the cover glass 341 may be attached without using the OCA film 8 unlike the present exemplary embodiment, that is, the display module 310 may be directly layered on the cover glass 341.

Although the edge type liquid crystal display device has been described in the aforementioned exemplary embodiment, a direct type liquid crystal display device may be manufactured by the same principle. For example, by using a back light unit instead of the reflection sheet 311, the direct type liquid crystal display device may be implemented.

An adhesive 330 and side dams 343 have the same configurations as those of the adhesive 130 and the side dams 143 described above, and thus the detailed descriptions thereof will not be provided. Further, a method for manufacturing the display device 300 of the present exemplary embodiment is the same as the aforementioned method, and thus the detailed descriptions thereof will not be provided.

### Third Exemplary Embodiment

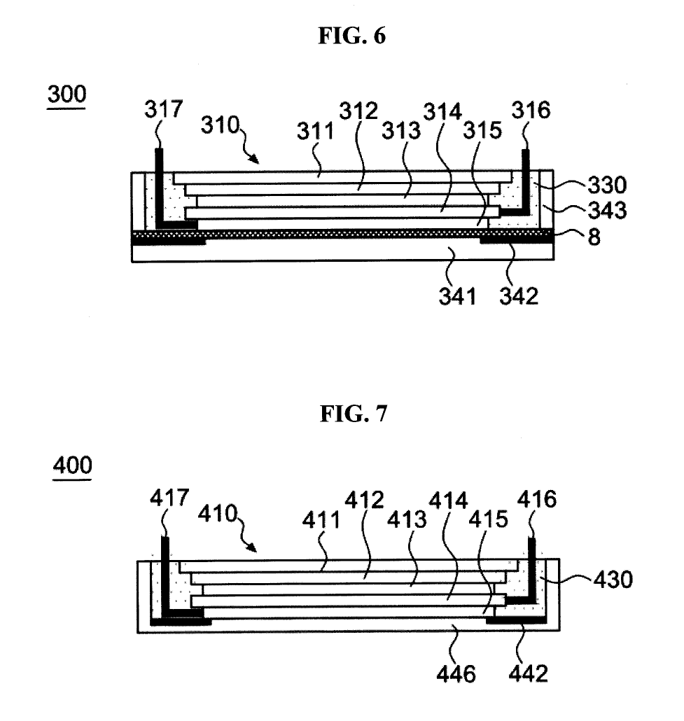

FIG. 7 is a schematic side view of a flat panel display device according to a third exemplary embodiment of the present invention.

The third exemplary embodiment illustrated in FIG. 7 has the same configurations as those of the display module 310 and the adhesive 330 of the second exemplary embodiment, and thus the descriptions thereof will not be presented. A difference between the third exemplary embodiment and the second exemplary embodiment will be described in detail.

A flat panel display device 400 according to the third exemplary embodiment of the present invention includes a case 446 corresponding to a configuration in which the cover glass 341 and the outer cases 343 of the flat panel display device 300 are integrally formed.

The case 446 may have a “∈”-shaped cross section, and a display module 410 and an adhesive 430 may be included in an inner space of the case. The case 446 may be made from a transparent soft material, and the flat panel display device 400 may be manufacturing by directly layering the display module 410 within the case 446. Accordingly, step S50 of removing and step S60 of attaching the outmost plate of FIG. 2 may not be performed.

Light blocking layers 442 made from a material through which light is not transmitted may be formed at edges on a bottom of the case 446. Further, a screen display area of the case 446 may be open as an opening, and a cover glass such as a tempered glass may be attached into the opening.

The exemplary embodiments of the present invention have been described in more detail with reference to the accompanying drawings, but the present invention is not limited to the exemplary embodiments. It will be apparent to those skilled in the art that various modifications can be made without departing from the technical sprit of the invention. Accordingly, the exemplary embodiments disclosed in the present invention are used not to limit but to describe the technical spirit of the present invention, and the technical spirit of the present invention is not limited to the exemplary embodiments. Therefore, the exemplary embodiments described above are considered in all respects to be illustrative and not restrictive. The protection scope of the present invention must be interpreted by the appended claims and it should be interpreted that all technical spirits within a scope equivalent thereto are included in the appended claims of the present invention.

For, example, it has been described that the exemplary embodiments of the present invention are applied to the electrophoretic display device and the liquid crystal display device, but the present invention is not limited to the aforementioned devices. The exemplary embodiments of the present invention may be applied to a plasma panel display device, an organic light-emitting display device, and other various flat panel display device.

For example, the flat panel display device 100 (200, 300, 400) of the exemplary embodiments of the present invention may also be applied to a flexible display device. In the existing flexible display device, there is a big problem that the OCA films between the display panel and the optical members of the display module 110 (210, 310, 410) are peeled off. However, when the flexible display device is implemented by using the flat panel display device 100 (200, 300, 400), since the display panel and the optical members, which constitute the respective layers of the display module 110 (210, 310, 410), are attached to each other, the conventional problem can be solved. When the flat panel display device 100 (200, 300, 400) is implemented as the flexible display device, some layers of the layers of the display module 110 (210, 310, 410) may be manufactured attached to each other using the adhesive 130 (230, 330, 430).

1. A flat panel display device comprising:
a display module that is formed by layering a flat display panel and one or more optical members having a pair of flat planes; and
an adhesive that occupies mold spaces formed so as to include sides of the display module and is cured while adhering to the sides of the display module,
wherein the panel of a flat display panel and the one or more optical members that constitute the display module are fixed to each other by the cured adhesive.

2. The flat panel display device according to claim 1, wherein the adhesive is a light curing adhesive or a heat curing adhesive.

3. The flat panel display device according to claim 1,
wherein the flat display panel is an electrophoretic display panel,
the optical members include a touch panel and a light guide plate,
the display module is formed by sequentially layering the electrophoretic display panel, the touch panel and the light guide plate, and
an anti-glare film or a cover glass is attached to an outside of the light guide plate.

4. The flat panel display device according to claim 1,
wherein the flat display panel is a liquid crystal display panel,
the optical members include a reflection plate, a light guide plate, and a touch panel,
the display module is formed by sequentially layering the reflection plate, the light guide plate, the liquid crystal display panel and the touch panel, and
an anti-glare film or a cover glass is attached to an outside of the touch panel.

5. A method for manufacturing a flat panel display device, the method comprising:
forming a display module by layering a flat display panel and one or more optical members having a pair of flat planes;
forming dams so as to form mold spaces including sides of the display module;
injecting an adhesive into the mold spaces while applying a pressure so as to allow the flat display panel and the one or more optical members that constitute the display module to come in close contact with each other; and
curing the adhesive,
wherein the flat display panel and the one or more optical members that constitute the display module are fixed to each other by the adhesive.

6. The method for manufacturing a flat panel display device according to claim 5,
wherein the forming of the dams includes forming transparent side dams so as to face the sides of the display module,
the adhesive is a light curing adhesive, and
in the curing of the adhesive, light is radiated through the side dams to cure the light curing adhesive.

7. The method for manufacturing a flat panel display device according to claim 5,
wherein the forming of the dams includes forming side dams so as to face the sides of the display module and forming a lower dam so as to form bottoms of the mold spaces, and
wherein the method for manufacturing a flat panel display device further includes:
removing the lower dam after the curing of the adhesive, and
attaching an outmost plate to a bottom of the display module after removing the lower dam.

8. The method for manufacturing a flat panel display device according to claim 7, wherein the outmost plate is at least one of a cover glass, an anti-glare film, and a cover film.

9. The method for manufacturing a flat panel display device according to claim 7, wherein a material through which light is not transmitted is printed at edges of the outmost plate so as to allow an image display area of the flat display panel to be viewed from the outside.

10. A flat panel display device manufactured by the manufacturing method according to claim 5.

11. A flat panel display device manufactured by the manufacturing method according to claim 6.

12. A flat panel display device manufactured by the manufacturing method according to claim 7.

13. A flat panel display device manufactured by the manufacturing method according to claim 8.

14. A flat panel display device manufactured by the manufacturing method according to claim 9.
